(19) United States
(12) Patent Application Publication
(10) Pub. No.: US 2005/0285166 A1
(43) Pub. Date: Dec. 29, 2005

(54) Monitoring patterns for an imaging device and method of monitoring a process using the monitoring patterns

(76) Inventors: Jun-taek Lee, Suwon-si (KR); Byung-hyun Yim, Yongin-si (KR); Seok-ha Lee, Seoul (KR); Sun-yong Park, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/090,065

(22) Filed: Mar. 28, 2005

(30) Foreign Application Priority Data
Jun. 25, 2004 (KR) 2004-48038

(51) Int. Cl. H01L 31/062

(52) U.S. Cl. 257/292

(57) ABSTRACT

Monitoring patterns for an imaging device and a method of monitoring processing using the monitoring patterns are disclosed. Processing errors in the imaging device are detected and estimated by measuring resistances between main impurity regions and associated sub impurity regions in the monitoring patterns. Monitoring patterns corresponding to mis-aligned regions in the imaging device have varying resistances between the main impurity region and the associated sub impurity regions.

### BACKGROUND OF THE INVENTION

1. Field of the Invention

The present invention relates generally to monitoring patterns for an imaging device, and more particularly to monitoring patterns for an imaging device allowing for simultaneous estimation of defective photolithography and defective diffusion in the imaging device, and a method of monitoring a process using the monitoring patterns.

A claim of priority is made to Korean Patent Application No. 10-2004-0048038 filed on Jun. 25, 2004, the disclosure of which is incorporated herein by reference in its entirety.

2. Description of the Related Art

Digital imaging devices typically convert optical signals into electrical signals. Such imaging devices include charge coupled devices (CCDs) and complementary metal oxide semiconductor (CMOS) image sensors (hereafter referred to as “CISs”). A CCD typically comprises a plurality of metal oxide semiconductor (MOS) capacitors and operates by using the migration of charges (carriers) induced by light incident to an imaging surface. Most conventional CISs are characterized by a plurality of pixels and a respective CMOS circuit controlling output signals from each unit pixel.

CCDs and CISs generally include photodiodes which convert light energy into electrical signals, and transfer media such as MOS transistors or MOS capacitors transferring the electrical signals to storage and/or processing elements. A CIS will be described as one example of an imaging device.

Referring to FIG. 1, a CIS comprises a photodiode 25 formed in a predetermined region of a semiconductor substrate 10. Photodiode 25 is formed by a PN junction consisting of an n-type impurity region 20 and a p-type impurity region 15. A transfer gate 30 used to transfer an electrical signal generated by photodiode 25 is formed on one side of photodiode 25. A floating diffusion region 35 used to store a signal generated by photodiode 25 is formed on one side of transfer gate 30. Photodiode 25 and floating diffusion region 35 are formed using a photolithography process, ion implantation, and diffusion. Transfer gate 30 is formed using photolithography. An example of the CIS device formed according to the above description is disclosed in U.S. Pat. No. 6,486,498, the subject matter of which is hereby incorporated by reference.

Characteristics of the foregoing imaging device are determined by various parameters related to imaging, including sensitivity, lag, blooming and smear. The values of these parameters are typically affected by a fabrication process used to create the imaging device. In other words, where misalignment occurs during the photolithography process or an impurity is incompletely diffused due to a defective thermal treatment following ion implantation, sensitivity of the screen is degraded, and lag, blooming or smear occurs. Therefore, it is necessary to estimate and then correct processing errors.

Conventionally, an initial quality evaluation for the imaging device is performed using a dummy test pattern formed while fabricating the imaging device.

FIG. 2 shows a typical dummy test pattern. The dummy test pattern comprises a monitoring pattern 50 having a MOS transistor structure formed by a gate 51, a drain 55a, and a source 55b. Using monitoring pattern 50 in the form of a MOS transistor, the processing error is estimated by measuring a threshold voltage (Vₜ) and a breakdown voltage (BV), which are characteristics of the MOS transistor.

Although processing error can be estimated by measuring the threshold voltage and the breakdown voltage of the monitoring pattern, the estimation is often highly inaccurate.

Moreover, where misalignment occurs during the photolithography process and, simultaneously, impurity regions are incompletely diffused, it is difficult to monitor these errors precisely. Furthermore, where gate 51 is shifted in the direction of a y-axis (shown in FIG. 2), the monitoring becomes impossible. Accordingly, an improved monitoring pattern structure and method of uses are required.

### SUMMARY OF THE INVENTION

The present invention provides monitoring patterns for an imaging device allowing for precise estimation of processing faults even in cases where multiple processing errors occur in combination. The present invention also provides a method of monitoring errors during processing using the monitoring patterns for the imaging device.

According to one embodiment of the present invention, monitoring patterns for an imaging device comprise a main impurity region and one or more sub impurity regions separated from the main impurity region by a uniform distance.

According to another embodiment of the present invention, monitoring patterns for an imaging device comprise a semiconductor substrate having a scribe line defining a plurality of imaging device regions and a plurality of monitoring patterns regularly arranged on the scribe line of the semiconductor substrate. Each of the respective monitoring patterns comprises a main impurity region and one or more sub impurity regions separated from the main impurity region by a uniform distance on upper, lower, right and left sides of the main impurity region. The plurality of monitoring patterns is arranged so that the distance between each main impurity region associated sub impurity regions increases sequentially.

According to another embodiment of the present invention, a method of monitoring processing in an imaging device using monitoring patterns comprises forming a plurality of main impurity regions on a scribe line of a semiconductor substrate. The method further comprises forming sub impurity regions at equal distances from respective upper, lower, right and left sides of the respective main impurity regions, thereby forming the plurality of monitoring patterns. The method further comprises measuring resistances between the main impurity region and the sub impurity regions on the upper, lower, right and left sides of the main impurity region in each monitoring pattern, and estimating a processing error for the imaging device according to a monitoring pattern having a varied resistance value between the main impurity region and the sub impurity regions on the upper, lower, right and left sides of the main impurity region.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIG. 1 is a cross-sectional view of a conventional CMOS imaging device;

FIG. 2 is a planar view of a conventional monitoring pattern for an imaging device;

FIG. 3 is a planar view of a monitoring pattern for an imaging device according to an embodiment of the present invention; and,

FIGS. 4 through 8 are planar views illustrating a method of estimating a processing error using the monitoring patterns for the imaging device according to an embodiment of the present invention.

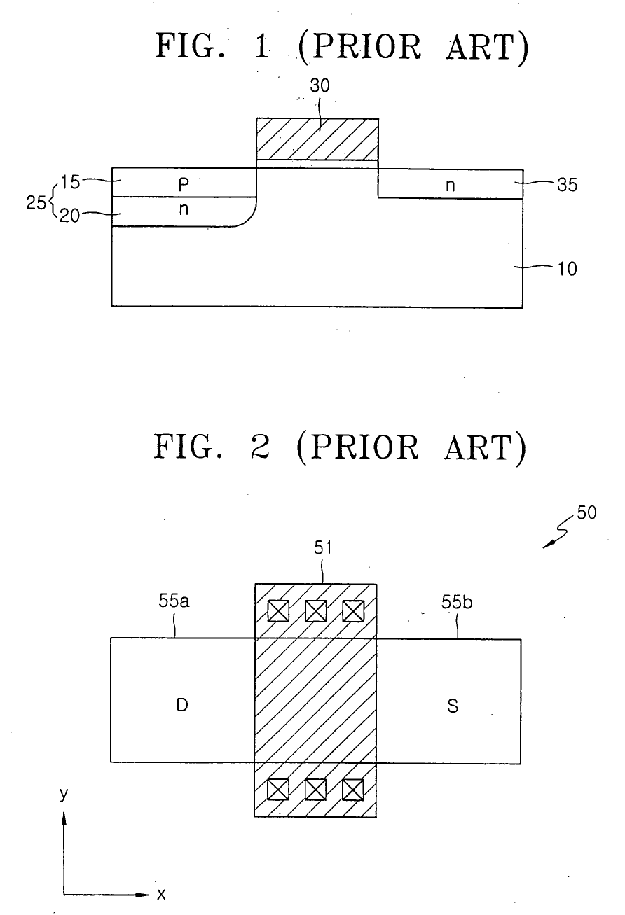

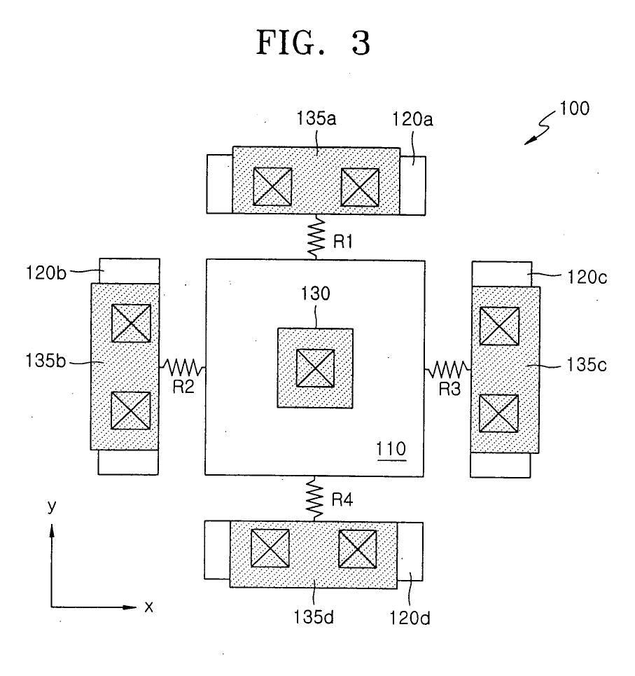

### DESCRIPTION OF THE EXEMPLARY EMBODIMENTS

Exemplary embodiments of the invention are described below with reference to the corresponding drawings. These embodiments are presented as teaching examples. The actual scope of the invention is defined by the claims that follow.

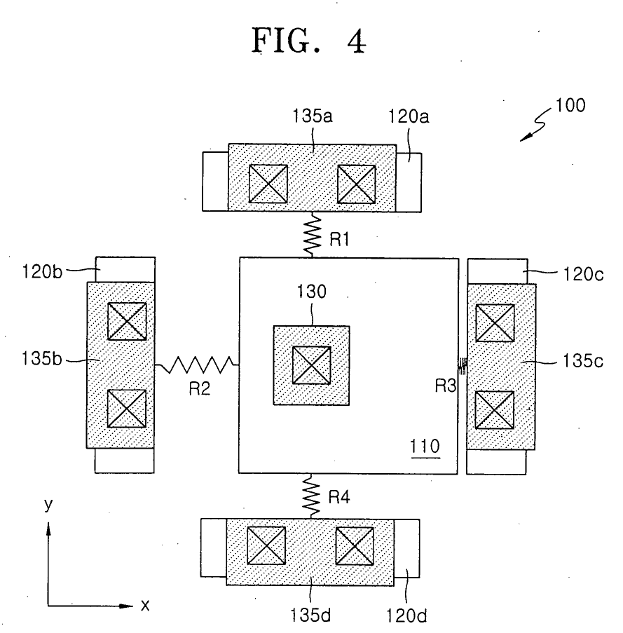

Referring to FIG. 3, a monitoring pattern 100 comprises a main impurity region 110 that will be subsequently tested, and at least one (here first through fourth) impurity sub-regions 120a, 120b, 120c, and 120d arranged around the outer perimeter of main impurity region 110. Viewing the monitoring pattern 100 from above (i.e., assuming z-view) as shown in FIG. 3, the one or more impurity sub-regions are said to be arranged near the upper, lower, right, and left sides of the main impurity region.

In one embodiment, main impurity region 110 has a rectangular shape or a square shape. In the context of currently contemplated imaging devices, main impurity region 110 may be formed in some embodiments with an impurity density substantially equal to that of an n-type impurity region (or p-type impurity region) forming a photodiode structure in the constituent imaging device.

As noted above, first through fourth impurity sub-regions 120a, 120b, 120c and 120d are formed respectively near upper, left, right, and lower sides of main impurity region 110. Respective impurity sub-regions 120a, 120b, 120c and 120d are each separated from main impurity region 110 by a defined distance. In one embodiment, this defined distance is uniform for all impurity sub-regions. In the illustrated embodiment, first and fourth impurity sub-regions 120a and 120d, and second and third impurity sub-regions 120b and 120c respectively face each other across main impurity region 110. In one embodiment, the respective impurity densities of the first through fourth impurity sub-regions 120a through 120d substantially equals the impurity density of a junction region in the constituent imaging device. The respective impurity densities may be n-type or p-type.

Main impurity region 110 and first through fourth impurity sub-regions 120a through 120d may be respectively connected with metal interconnects 130, 135a, 135b, 135c and 135d formed in one embodiment above or on top portions (i.e., in a z-direction with respect to FIG. 3) of main impurity region 110 and first through fourth impurity sub-regions 120a through 120d. The metal interconnects receive and transfer electrical signals.

The monitoring pattern as described above is formed in one embodiment by the following exemplary method.

A first resist pattern (not shown) is formed in a semiconductor substrate (not shown) using a photolithography process, thereby exposing a rectangular area in a predetermined portion of a scribe region of the semiconductor substrate. Exposed portions of the semiconductor substrate are ion implanted with a selected impurity. The first resist pattern is then removed using a conventional method, after which the implanted impurity is thermally treated to form main impurity region 110. Main impurity region 110 is typically formed simultaneously with a photodiode region found in the imaging device.

A second resist pattern (not shown) is then formed in the semiconductor substrate so as to expose predetermined sub-regions near the upper, lower, right, and left sides of the main impurity region 110. Preferably, each of the predetermined sub-regions exposed by the second resist pattern is separated from main impurity region 110 by a defined distance. The exposed sub-regions are ion implanted with a selected impurity, after which the second resist pattern is removed. The implanted impurity is then thermally treated to form impurity sub-regions 120a, 120b, 120c and 120d. Here, sub impurity regions 120a, 120b, 120c and 120d are typically formed simultaneously with a junction region found in the imaging device.

Thereafter, an insulating interlayer is formed on a top portion of the resultant structure. Then, predetermined portions of the insulating interlayer are etched to expose main impurity region 110 and impurity sub-regions 120a, 120b, 120c and 120d. Metal interconnects 130, 135a, 135b, 135c, and 135d are formed to contact exposed portions of main impurity region 110 and impurity sub-regions 120a, 120b, 120c and 120d.

In the exemplary monitoring pattern 100 formed above, because main impurity region 110 and impurity sub-regions 120a, 120b, 120c and 120d are separated by a defined uniform distance, respective uniform resistances R1, R2, R3 and R4 exist between main impurity region 110 and each impurity sub-region 120a, 120b, 120c and 120d. Resistances R1, R2, R3 and R4 exhibit constant and uniform values where there is no error or misalignment in the various process used to form the monitoring pattern. Where processing errors or structural misalignments are present, the resulting resistance values will vary. Hereinafter, variation of the resistance values resulting from processing error will be described in more detail.

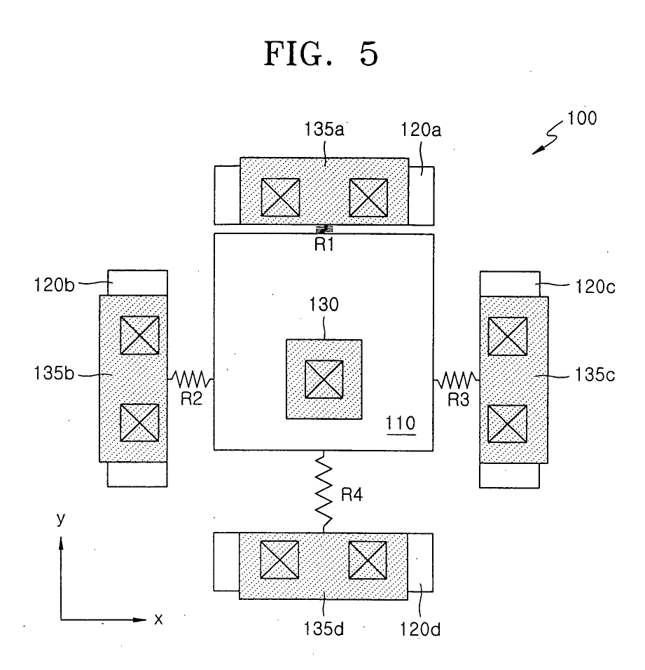

Referring to FIG. 4, where the first resist pattern defining main impurity region 110 is mis-aligned along the x-axis, the values of resistances R2 and R3 corresponding to the impurity sub-regions formed on the left and right sides of main impurity region 110 vary from design specification. For example, where the first resist pattern is mis-aligned to the right along the x-axis, resistance R3 is markedly decreased while resistance R2 is increased. In view of this result, misalignment of the first resist pattern defining main impurity region 110 is readily detected and therefore readily corrected.

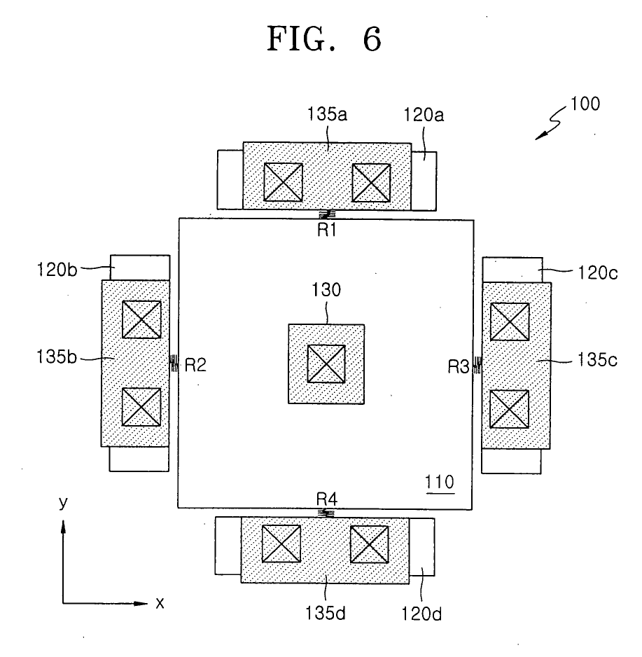

Referring to FIG. 5, where the first resist pattern defining main impurity region 110 is mis-aligned along the y-axis, the values of resistances R1 and R4 corresponding to impurity sub-regions formed on respective upper and lower sides of main impurity region 110 vary from design specification. For example, where the first resist pattern is mis-aligned upward along the y-axis, resistance R1 is markedly decreased while resistance R4 is increased. In view of this result, misalignment of the first resist pattern defining main impurity region 110 is readily detected and therefore readily corrected.

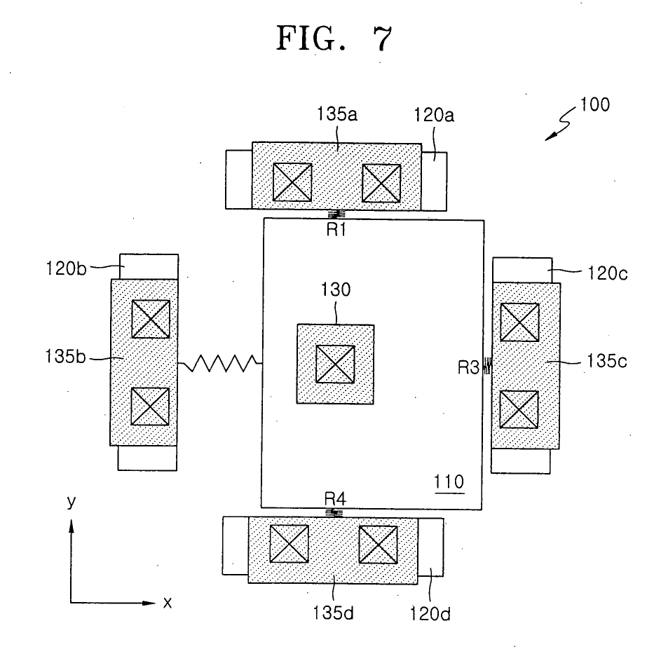

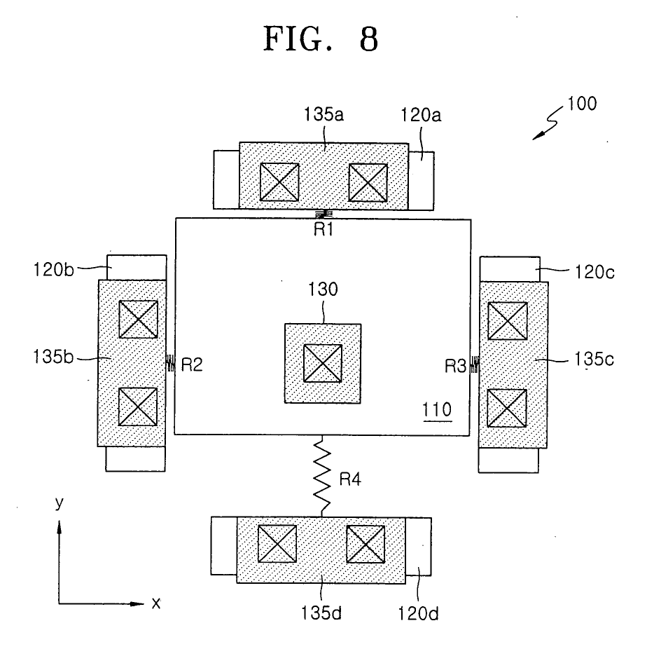

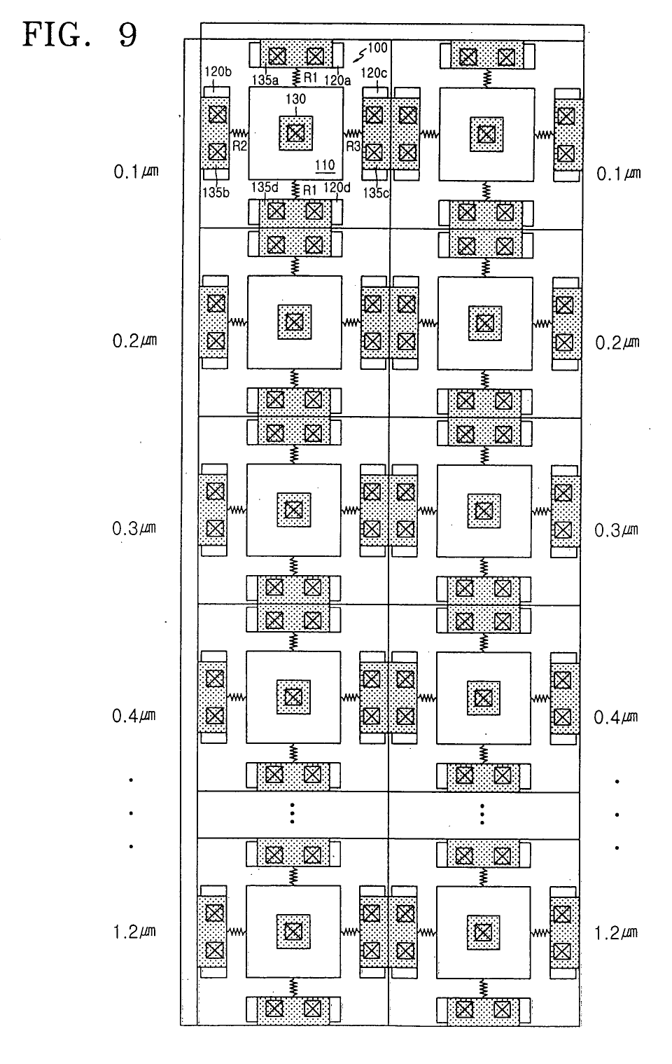

Meanwhile, where the impurity diffusion (thermal treatment) used to form main impurity region 110 is excessive, i.e., where the thermal treatment is performed for an improperly long time or at an unacceptably high temperature, the impurity forming main impurity region 110 will typically be excessively diffused. In this case, as shown in FIG. 6, resistances R1 through R4 corresponding to the surrounding impurity sub-regions will all be decreased. Where resistances R1 through R4 are determined to exist in this state, the diffusion of main impurity region 110 may be determined to be faulty, and can therefore be corrected.

Where the first resist pattern defining main impurity region 110 is mis-aligned along the x-axis and impurity diffusion is incompletely performed, as shown in FIG. 7, resistances R2 and R3 corresponding to impurity sub-regions formed on respective left and right sides of main impurity region 110 are varied, i.e., resistance R2 is increased and resistance R3 is decreased. Resistances R1 and R4 are also similarly decreased. In this case, it is readily determined that main impurity region 110 is mis-aligned along the x-axis and that impurity diffusion is poorly performed, all of which can thereafter be corrected.

Where the first resist pattern defining main impurity region 110 is mis-aligned along the y-axis and impurity diffusion is incompletely performed, as shown in FIG. 8, resistances R1 and R4 corresponding to impurity sub-regions formed on the upper or lower sides of main impurity region 110 are varied, i.e. resistance R4 is increased and resistance R1 is decreased. Resistances R2 and R3 are also similarly decreased. In this case, it is readily determined that main impurity region 110 is mis-aligned along the y-axis and that impurity diffusion is poorly performed, all of which can thereafter be corrected.

In sum, using the monitoring pattern according to the present invention, single or combined processing error(s) may be readily monitored in view of noted variations in resistance values associated with impurity sub-regions formed around a main impurity region. Not only the direction of mis-alignment (if any), but also diffusion density impairments may be noted and monitored in relation to the main impurity region.

Referring to FIG. 9, a plurality of monitoring patterns 100 is arranged regularly within a scribe line. In order to sequentially increase (or decrease) the resistance values in respective monitoring patterns 100, distances between main impurity region 110 and impurity sub-regions 120a, 120b, 120c and 120d are sequentially increased (or decreased). By sequentially increasing or decreasing the resistance values in respective monitoring patterns 100, an actual amount of misalignment occurring can be estimated by using monitoring pattern 100 at a point incurring an error.

For example, as shown in FIG. 9, the monitoring patterns are formed by sequentially increasing the distance between main impurity region 110 and impurity sub-regions 120a, 120b, 120c, and 120d by intervals of 0.1 μm. More specifically, the distance between main impurity region 110 and impurity sub-regions 120a, 120b, 120c and 120d is set to 0.1 μm in a first monitoring pattern. In a second monitoring pattern, the distance between main impurity region 110 and impurity sub-regions 120a, 120b, 120c and 120d is increased by an interval of 0.1 μm. In conformity with this rule, monitoring patterns 100 are arranged in relation to a sequentially increasing arrangement defined by an incremental distance.

After forming monitoring patterns 100 in accordance with the above-described arrangement, the variation of the resistances in monitoring patterns 100 is monitored. For example, where the resistance is varied in the monitoring pattern arranged with distances of 0.5 μm and resistance R3 within that monitoring pattern is varied, it can be determined that the actual photodiode region is mis-aligned rightward by as much as 0.5 μm. Using this technique, the actual distance of the mis-alignment can be precisely estimated.

In this embodiment, although the distance between main impurity region 110 and impurity sub-regions 120a, 120b, 120c and 120d is increased by intervals of 0.1 μm, it is typically arranged with intervals smaller than 0.1 μm in order to more precisely estimate the distance of the mis-alignment.

According to the embodiment of the present invention as described above, impurity sub-regions are formed around a main impurity region to thereby construct a monitoring pattern. By measuring resistances between the main impurity region and the surrounding impurity sub-regions in the monitoring pattern, errors in the fabrication process may be readily detected. Where the measured resistances between the main impurity region and the impurity sub-regions match intended values, the fabrication process is determined to be error free. Where the measured resistances deviate from the intended values, mis-alignment of an imaging device region (such as a photodiode region) simultaneously formed with the main impurity region and poor diffusion in the device are readily estimated by the position of the deviating resistances.

Furthermore, a plurality of monitoring patterns are regularly arranged within a scribe line of a wafer having sequentially increasing resistance values. By providing this type of monitoring pattern, any reasonable mis-aligned distance can be estimated upon consideration of the distance of the monitoring patterns where resistance values are varied.

As described above, defective photolithography and the diffusion (ion implantation) processes are readily monitored using the monitoring patterns. The processing is readily corrected in accordance with the result of the monitoring. Therefore, characteristics such as picture quality in an imaging device are readily improved.

The foregoing exemplary embodiments are teaching examples. Those of ordinary skill in the art will understand that various changes in form and details may be made to the exemplary embodiments without departing from the scope of the present invention which is defined by the following claims.

1. A monitoring pattern associated with an imaging device comprising:
a main impurity region; and,
a plurality of impurity sub-region, each separated from the main impurity region by a defined distance.

2. The monitoring pattern of claim 1, wherein the plurality of impurity sub-regions comprises impurity sub-regions formed near at least two of upper, lower, right and left sides of the main impurity region.

3. The monitoring patterns of claim 2, wherein the main impurity region has a rectangular shape.

4. The monitoring patterns of claim 3, wherein the main impurity region has a square shape.

5. The monitoring patterns of claim 1, further comprising:
metal interconnects formed on top portions of the main impurity region and the plurality of impurity sub-regions.

6. The monitoring patterns of claim 1, wherein an impurity density in the plurality of impurity sub-region equals the impurity density of a junction region in the imaging device.

7. The monitoring patterns of claim 6, wherein the impurity forming the plurality of impurity sub-regions is n-type or p-type.

8. The monitoring patterns of claim 1, wherein the main impurity region has an impurity density equal to that of an n-type impurity region or p-type impurity region of a photodiode in the imaging device.

9. A monitoring pattern for an imaging device comprising:
a semiconductor substrate comprising a scribe line defining a plurality of imaging device regions; and,
a plurality of monitoring patterns regularly arranged in relation to the scribe line;
wherein each of the respective monitoring patterns comprises a main impurity region and a plurality of impurity sub-regions respective separated from upper, lower, right or left sides of the main impurity region by a defined distance; and,
wherein the defined distance for each one of the plurality of monitoring patterns is different.

10. The monitoring patterns of claim 9, wherein respective defined distances associated with the plurality of monitoring patterns are sequentially varied one from another by a defined incremental distance.

11. The monitoring patterns of claim 9, wherein for each one of the plurality of monitoring patterns, the main impurity region has a rectangular shape and the impurity sub-regions are formed in regions corresponding to respective sides of the main impurity region.

12. The monitoring patterns of claim 10, wherein the main impurity region has a square shape.

13. A method of monitoring and detecting a fabrication processing error in a process adapted to form an imaging device, the method comprising:
forming a plurality of monitoring patterns, each monitoring pattern comprising a main impurity region and a corresponding plurality of impurity sub-regions, each impurity sub-region being formed at a defined distance from an upper, lower, right or left side of the main impurity region; and,
for each one of the plurality of monitoring patterns, measuring resistances between the main impurity region and the corresponding plurality impurity sub-regions; and,
determining a fabrication processing error in relation to the measured resistances.

14. The method of claim 13, wherein the defined distance for each one of the plurality of monitoring patterns is sequentially varied in accordance with a defined incremental distance.

15. The method of claim 14, wherein the defined incremental distance is 0.1 μm or less.
